(19) United States
(12) Patent Application Publication
(10) Pub. No.: US 2009/0061539 A1
(43) Pub. Date: Mar. 5, 2009

(54) Substrate holding structure and method of producing semiconductor device using the same

(75) Inventor: Yoshikazu Motoyama, Miyazaki (JP)

Correspondence Address: KUBOTERA & ASSOCIATES, LLC, Suite 202, 200 Daingerfield Road, Alexandria, VA, 22314, US

(73) Assignee: Oki Electric Industry Co., Ltd.

(21) Appl. No.: 12/230,375

(22) Filed: Aug. 28, 2008

(30) Foreign Application Priority Data
Sep. 3, 2007 (JP) 2007-227305

(51) Int. Cl. H01L 21/66; H05B 3/68

(52) U.S. Cl. 438/5; 219/444.1; 257/E21.53

(57) ABSTRACT

A substrate holding structure includes a wafer stage having a first main surface and a second main surface opposite to the first main surface. A substrate placing area is defined on the first main surface. The substrate holding structure further includes a static capacity measurement electrode having a center circular electrode and at least one circular ring electrode for measuring a combined capacity among a substrate to be placed in the substrate placing area, the center circular electrode, and the circular ring electrode; at least one temperature measurement unit; an electrode control unit connected to the center circular electrode and the circular ring electrode; a temperature control unit connected to the temperature measurement unit and the temperature adjustment unit; a storage unit; a calculation unit connected to the storage unit; and a control unit connected to the electrode control unit and the temperature control unit.

### BACKGROUND OF THE INVENTION AND RELATED ART STATEMENT

The present invention relates to a substrate holding structure and a method of producing a semiconductor device using the substrate holding structure. In particular, the present invention relates to a substrate holding structure having a wafer stage used for a semiconductor production process, and a method of producing a semiconductor device using the substrate holding structure.

In a semiconductor production process, variety of processes such as a film forming process, an etching process, and the likes are performed with respect to a semiconductor wafer (referred to as a wafer). In the variety of processes, it is necessary to maintain flatness of the wafer when the wafer is fixed to a wafer stage.

In the semiconductor production process, a variety of configurations have been known for measuring a warpage of a wafer. For example, in order to prevent a warpage of a wafer, there has been known a configuration in which a Vacuum Chuck™ is disposed in a wafer stage. In the configuration, the vacuum chuck generates a sucking force, so that a lower surface of the wafer is sucked to a surface of the wafer stage, thereby maintaining a flatness of the wafer.

In the wafer stage with the vacuum chuck, an electrode is disposed in the wafer stage within a thickness thereof for measuring a static capacity between the wafer and the electrode when the wafer is held. Accordingly, it is possible to confirm a state of holding the wafer according to the static capacity (refer to Patent Reference).

Patent Reference: Japanese Patent Publication No. 04-216650

In the conventional wafer stage with the vacuum chuck, or a substrate holding structure, it may be difficult to securely maintain the flatness of the wafer due to dust and the likes. For example, when a specific process such as a film forming process is performed on the wafer stage, it is difficult to accurately set a timing when the warpage of the wafer due to temperatures of the wafer stage and the wafer is removed, thereby prolonging a wait time.

Further, right after a specific process and before the wafer is transported from a processing room, even if it is possible to detect the warpage of the wafer due to temperatures of the wafer stage and the wafer, it takes a long period of time to naturally remove the warpage, thereby prolonging a wait time until it is possible to transport the wafer from the processing room.

Further, when the wafer is transported from the processing room after a specific process, if the wafer is placed on a pre-heated wafer stage, a similar problem may occur. That is, since it is difficult to accurately set a timing when the warpage of the wafer is removed, it is difficult to shorten the wait time until the warpage of the wafer is removed. Due to the problems described above, a production efficiency of a semiconductor device or a product is deteriorated.

In view of the problems described above, an object of the present invention is to provide a substrate holding structure and a method of producing a semiconductor device using the substrate holding structure capable of solving the problems of the conventional substrate holding structures. In the substrate holding structure of the present invention, a static capacity between a wafer stage and a wafer is continuously measured in a real time, so that a temperature of the wafer stage is controlled according to the static capacity thus measured.

In the present invention, it is possible to detect a timing when a warpage of the wafer is removed in a short period of time, thereby shortening a time of a production process.

Further objects and advantages of the invention will be apparent from the following description of the invention.

### SUMMARY OF THE INVENTION

In order to attain the objects described above, according to a first aspect of the present invention, a substrate holding structure includes a wafer stage having a first main surface and a second main surface opposite to the first main surface. A substrate placing area is defined on the first main surface.

The substrate holding structure further includes a static capacity measurement electrode disposed in the wafer stage. The static capacity measurement electrode includes a center circular electrode and at least one circular ring electrode disposed away from the center circular electrode and surrounding the center circular electrode. Accordingly, the static capacity measurement electrode measures a combined capacity among a substrate to be placed in the substrate placing area, the center circular electrode, and the circular ring electrode.

The substrate holding structure further includes at least one temperature measurement unit disposed at a space between the center circular electrode and the circular ring electrode, or a space between the circular ring electrodes; a temperature adjustment unit disposed in the wafer stage; an electrode control unit connected to the center circular electrode and the circular ring electrode; a temperature control unit connected to the temperature measurement unit and the temperature adjustment unit; a storage unit; a calculation unit connected to the storage unit; and a control unit connected to the electrode control unit and the temperature control unit.

According to a second aspect of the present invention, a method of producing a semiconductor device includes the steps of:

preparing the substrate holding structure with the configuration described above;

placing a substrate in the substrate placing area of the wafer stage;

measuring a static capacity generated between the static capacity measurement electrode and the substrate with the static capacity electrode and the electrode control unit to obtain static capacity data at least when the substrate is placed in the substrate placing area;

comparing the static capacity data with lookup data stored in the storage unit and indicating a relationship between a warpage amount and a static capacity using the calculation unit;

determining an operation of the temperature adjustment unit using the calculation unit so that a warpage of the wafer is removed or becomes within an allowable range using the calculation unit; and

controlling the temperature adjustment unit using the control unit to adjust a temperature of the wafer stage so that the warpage of the wafer is removed or becomes within the allowable range.

When a wafer in a warped state is transported, the wafer may fall off from a wafer stage. In the substrate holding structure of the present invention, it is possible to prevent the wafer from falling off from the wafer stage and being broken, thereby preventing productivity from lowering due to an necessary idle time in transporting the wafer to a next step.

In the substrate holding structure of the present invention, it is possible to monitor a warped state of the substrate placed on the wafer stage all the time, that is, to measure an extent of the warpage of the substrate in a real time. Accordingly, it is possible to quickly monitor generation and removal of the warpage of the substrate.

Further, in the substrate holding structure of the present invention, it is possible to quickly perform a process suitable for the state of the warpage of the wafer, that is, the static capacity thus measured. More specifically, when the warpage of the wafer is detected, the wafer stage is cooled or heated without waiting until the warpage of the wafer is spontaneously removed. Accordingly, it is possible to proactively control a so-called in-surface temperature of the wafer, and to remove the warpage of the wafer in a short period of time.

As a result, it is possible to minimize a period of time when the wafer is warped, and to move the wafer to a next step quickly after the warpage of the wafer is removed, thereby shortening a production time.

Further, in the substrate holding structure of the present invention, it is possible to measure the static capacity of the wafer and remove the warpage of the wafer piece by piece. Accordingly, even when the substrate is formed of silicon having a thickness less than 200 μm or sapphire having a low thermal conductivity, i.e., a wafer having a tendency of an individual difference in an extent of warpage, it is possible to efficiently produce the semiconductor device with high yield.

Further, in the substrate holding structure of the present invention, the static capacity measurement electrode includes the center circular electrode and at least one circular ring electrode disposed away from the center circular electrode. Accordingly the static capacity measurement electrode measures the combined capacity among the substrate to be placed in the substrate placing area, the center circular electrode, and the circular ring electrode. As a result, as opposed to a conventional method, it is not necessary to contact a probe needle directly with the substrate to be placed.

Further, it is not necessary to remove a film formed on the substrate to directly expose the substrate for the measurement. Accordingly, it is possible to easily measure the static capacity, that is, the state of the warpage of the substrate.

### BRIEF DESCRIPTION OF THE DRAWINGS

FIGS. 1(A) and 1(B) are schematic views showing a wafer stage according to an embodiment of the present invention, wherein FIG. 1(A) is a plan view of the wafer stage, and FIG. 1(B) is a schematic sectional view of the wafer stage taken along a projected line 1(B)-1(B) in FIG. 1(A);

FIG. 2 is a block diagram showing a substrate holding structure according to the embodiment of the present invention;

FIG. 3 is a flow chart showing an operation of the substrate holding structure according to the embodiment of the present invention; and

FIG. 4 is a graph showing a relationship between a static capacity and a warpage amount according to the embodiment of the present invention.

### DETAILED DESCRIPTION OF PREFERRED EMBODIMENTS

Hereunder, embodiments of the present invention will be explained with reference to the accompanying drawings. In the following description of the present invention, each of the drawings is illustrated schematically in terms of a shape, a size, and a dimensional relationship for explaining the embodiments of the present invention, and the present invention is not limited to the shape, the size, and the dimensional relationship shown in the drawings.

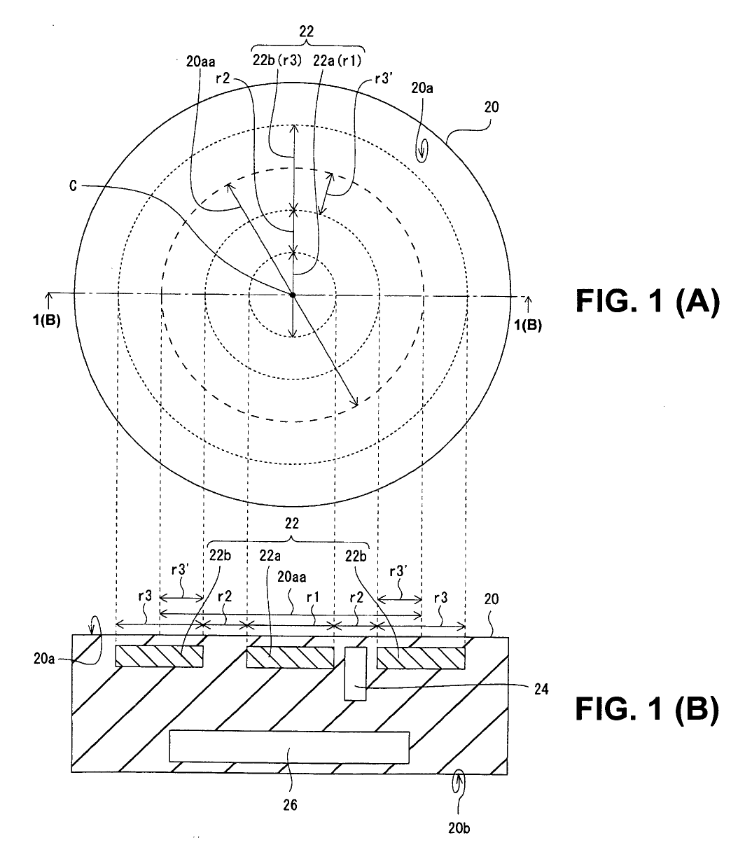

According to an embodiment of the present invention, a configuration of a wafer stage 20, i.e., a main element of a substrate holding structure 10, will be explained with reference to FIGS. 1(A) and 1(B).

FIGS. 1(A) and 1(B) are schematic views showing the wafer stage 20 according to the embodiment of the present invention. More specifically, FIG. 1(A) is a plan view of the wafer stage 20, and FIG. 1(B) is a schematic sectional view of the wafer stage 20 taken along a projected line 1(B)-1(B) in FIG. 1(A).

As shown in FIGS. 1(A) and 1(B), the substrate holding structure 10 includes the wafer stage 20 formed of a flat plate of a parallel plate type.

In the embodiment, the wafer stage 20 is placed in a process room, i.e., a chamber for performing a film forming process such as chemical vapor deposition (CVD); or is temporarily placed outside the process room before being transported; or is attached to a transportation robot for receiving a wafer upon taking out the wafer from the chamber after the wafer bis processed.

In the embodiment, the wafer stage 20 has a circular shape in a plan view viewed from an upper surface thereof or a lower surface thereof. Note that the wafer stage 20 may have an arbitrary plane shape such as a rectangular according to a shape of an object to be processed.

In the embodiment, the wafer stage 20 is preferably formed of a well-known material containing a main component such as alumina (Al₂O₃), i.e., a so-called ceramic flat plate.

In the embodiment, the wafer stage 20 includes a first main surface 20a as an upper surface thereof, and a second main surface 20b in parallel and opposite to the first main surface 20a.

In the embodiment, an object to be processed is held on the first main surface 20a. The object to be processed may include a substrate, for example, a semiconductor wafer such as a silicon wafer. When the wafer, i.e., the object to be processed, has a diameter of 6 inches (15.2 cm), the wafer stage 20 preferably has a diameter of about 200 mm and a thickness in a range of about 10 mm to 20 mm.

In the embodiment, a substrate placing area 20aa (an area surrounded with a hidden line in FIG. 1(A)) is defined on the first main surface 20a. The substrate placing area 20aa has a regular circular shape arranged coaxially with a center point C of the wafer stage 20. The wafer (not shown) is placed in the substrate placing area 20aa.

As shown in FIG. 1(B), a static capacity measurement electrode 22 is disposed in the wafer stage 20 between the first main surface 20a and the second main surface 20b for measuring a static capacity generated between the wafer placed on the wafer stage 20 and the static capacity measurement electrode 22.

In the embodiment, it is necessary to form the static capacity measurement electrode 22 of a material capable of withstanding against a temperature in a process in which the wafer stage 20 is exposed. Accordingly, the static capacity measurement electrode 22 is preferably formed of a thin plate of titanium (Ti). Further, the static capacity measurement electrode 22 preferably has a thickness of about 1 mm. Still further, the static capacity measurement electrode 22 is preferably formed of a plurality of thin plates.

In the embodiment, the static capacity measurement electrode 22 is formed of electrodes formed in a thin plate shape and having two types of shapes. More specifically, the static capacity measurement electrode 22 includes a center circular electrode 22a having a circular contour as a whole and the center point C, and a circular ring electrode 22b having a circular ring shape in a plan view and arranged coaxially with the center point C. The circular ring electrode 22b is arranged away from the center circular electrode 22a. Further, the center circular electrode 22a and the circular ring electrode 22b have surfaces on a side of the first main surface 20a on a same plane.

In the embodiment, the center circular electrode 22a is arranged within a contour of the center circular electrode 22aa in a plan view. More specifically, the center circular electrode 22a has a diameter smaller than that of the substrate placing area 20aa. The circular ring electrode 22b has an outer diameter larger than a diameter of the substrate placing area 20aa, and is arranged such that the outer diameter thereof is situated outside the substrate placing area 20aa. That is, the circular ring electrode 22b is arranged such the contour thereof overlaps with a contour of the substrate placing area 20aa in a plan view.

In the embodiment, the static capacity measurement electrode 22 has a width, i.e., a diameter of the center circular electrode 22a and a shortest distance between an inner diameter and the outer diameter of the circular ring electrode 22b, is preferably set within a range of about 10 mm and 45 mm.

In the embodiment, the circular ring electrode 22b may be formed of a plurality of circular ring electrodes having different widths. In this case, a plurality of the circular ring electrodes 22b is arranged coaxially with the center point C. Further, an outer most circular ring electrode 22b is arranged such that an area thereof overlaps with an outer contour of the first main surface 20a in a plan view.

In the embodiment, a temperature measurement unit 24 is embedded in the wafer stage 20 within a thickness thereof for monitoring a temperature of the wafer stage 20 in a real time. The temperature measurement unit 24 monitors the temperature of the wafer stage 20 in a real time, so that the temperature of the wafer stage 20 is controlled to be a specific set temperature and is maintained at the specific set temperature.

In the embodiment, the temperature measurement unit 24 is preferably formed of a well-known device such as a thermocouple. Further, the temperature measurement unit 24 is disposed in the wafer stage 20 in a space between the center circular electrode 22a and the circular ring electrode 22b situated away from each other, and is situated away from the center circular electrode 22a and the circular ring electrode 22b.

In the embodiment, one temperature measurement unit 24 is embedded in the wafer stage 20 within a thickness thereof. It is possible to provide two or more, more preferably four to six, temperature measurement units 24. In this case, the temperature measurement units 24 are disposed in a space between the circular ring electrodes 22b or outside the outer most circular ring electrode 22b along the contour of the center circular electrode 22a and/or the circular ring electrode 22b with an equal interval therebetween.

With the configuration described above, it is possible to accurately obtain a temperature distribution of the wafer stage 20, especially on a side of the first main surface 20a, thereby making it possible to uniformly control the temperature of the wafer stage 20. As a result, it is possible to accurately remove a warpage of the wafer.

In the embodiment, a temperature adjustment unit 26 is disposed in the wafer stage 20 within a thickness thereof below the static capacity measurement electrode 22 and the temperature measurement unit 24. The temperature adjustment unit 26 heats or cools the wafer stage 20, so that the substrate held on the first main surface 20a is indirectly heated or cooled. The temperature adjustment unit 26 is formed of a well-known heating element used for a conventional wafer stage such as a heater for heating and a well-known cooling element such as a Peltier device, i.e., a chiller.

In the embodiment, the temperature adjustment unit 26 includes an arbitrary configuration for quickly adjusting a temperature of the object to be processed uniformly. More specifically, in the case of the heater, it is preferred that the temperature adjustment unit 26 has a large heat capacity. Accordingly, it is possible to minimize a temperature decrease due to heat absorption of the object to be processed, thereby making it possible to remove the warpage of the wafer in a short period of time through the temperature adjustment.

In the embodiment, the temperature adjustment unit 26 is capable of setting the temperature of the wafer stage 20 in a range of −100° C. and 1,200° C. According to the static capacity, i.e., the warpage amount of the substrate, measured with the static capacity measurement electrode 22, the temperature measurement unit 24 and the temperature adjustment unit 26 are preferably configured to operate under, for example, PID (Proportional Integral Differential) control.

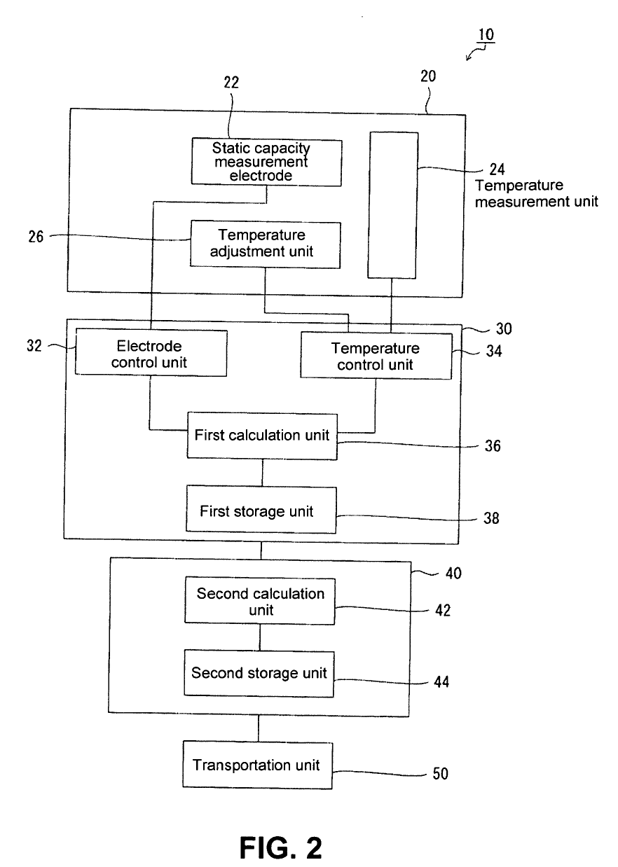

A configuration of the substrate holding structure 10 will be explained with reference to FIG. 2. FIG. 2 is a block diagram showing the substrate holding structure 10 according to the embodiment of the present invention.

As shown in FIG. 2, the substrate holding structure 10 includes the wafer stage 20 described above. A first control unit 30 (described later) is disposed outside the wafer stage 20. The first control unit 30 includes an electrode control unit 32, a temperature control unit 34, a first calculation unit 36, and a first storage unit 38.

In the embodiment, the static capacity measurement electrode 22 of the wafer stage 20 is connected to the electrode control unit 32, so that the electrode control unit 32 controls an operation of the static capacity measurement electrode 22 for measuring the static capacity. The temperature control unit 32 is connected to the first calculation unit 36. The temperature control unit 32 transmits a value of the static capacity measured with the static capacity measurement electrode 22, i.e., static capacity data, to the first calculation unit 36. Further, the temperature control unit 32 transmits a control signal from the first calculation unit 36 to the static capacity measurement electrode 22.

In the embodiment, the temperature control unit 34 is connected to the temperature measurement unit 24 and the temperature adjustment unit 26 for controlling an operation of the temperature measurement unit 24 and the temperature adjustment unit 26. Further, the temperature control unit 34 controls the temperature measurement unit 24 to measure the temperature of the wafer stage 20, so that the temperature adjustment unit 26 dynamically adjusts the temperature of the wafer stage 20. Note that the temperature control unit 34 is also connected to the first calculation unit 36.

In the embodiment, the temperature measurement unit 24 and the temperature adjustment unit 26 include a hardware resource connected thereto such as an A/D converter and the likes for operating the temperature measurement unit 24 and the temperature adjustment unit 26. As described above, the first control unit 30 includes the first calculation unit 36 and the first storage unit 38 connected thereto. The first control unit 30 corresponds to a functional unit based on a well-known computer hardware resource and a software resource connected thereto for cooperating.

More specifically, the first calculation unit 36 corresponds to a functional unit having a calculation function such as CPU or MPU, and the first storage unit 38 corresponds to a functional unit such as a memory module or a hard disk drive capable of reading, writing, and storing data. The first storage unit 38 stores a program and data such as a specific parameter and the likes in a readable form in advance for controlling the electrode control unit 32 and the temperature control unit 34.

In the embodiment, the first control unit 30 may include an arbitrary input device (not shown) such as a mouse and a keyboard; a display device such as a display for visualizing data; and the likes.

In the embodiment, the first control unit 30 is connected to a second control unit 40. The second control unit 40 includes a second calculation unit 42, and a second storage unit 44 connected to the second calculation unit 42. The second control unit 40 corresponds to a functional unit based on a well-known computer hardware resource and a software resource connected thereto for cooperating.

In the embodiment, the second control unit 40 is a main control device of the substrate holding structure 10 (referred to as a main control unit). The second calculation unit 42 has a calculation function and corresponds to a functional unit for controlling other functional units. The second storage unit 44 corresponds to a functional unit capable of reading, writing, and storing data.

In the embodiment, the second storage unit 44 stores a program and data such as a specific parameter and the likes in a readable form in advance for controlling the first control unit 30 and eventually the wafer stage 20. The data include, for example, control condition information. More specifically, a relationship between the static capacity and the warpage amount of the object to be processed is determined in advance, and the relationship is stored as a reference data group, i.e., lookup data, to be compared with an actual measurement result. The reference data group includes data corresponding to the static capacity of the object to be processed without the warpage (referred to as zero data).

In the embodiment the first control unit 30 and the second control unit 40 may be integrated into one control unit. That is, the electrode control unit 32 and the temperature control unit 34 are combined into the second control unit 40. Further, the first calculation unit 36 and the second calculation unit 42 may be integrated into one calculation unit, and the first storage unit 38 and the second storage unit 44 are integrated into one storage unit.

In the embodiment, the second control unit 40 is connected to a transportation unit 50. The transportation unit 50 includes a transportation robot having a well-known configuration for transporting the object to be processed such as a wafer. Further, the transportation unit 50 includes a transportation arm for placing the object to be processed on the wafer stage 20, and removing the object to be processed from the wafer stage 20 after a specific process is performed.

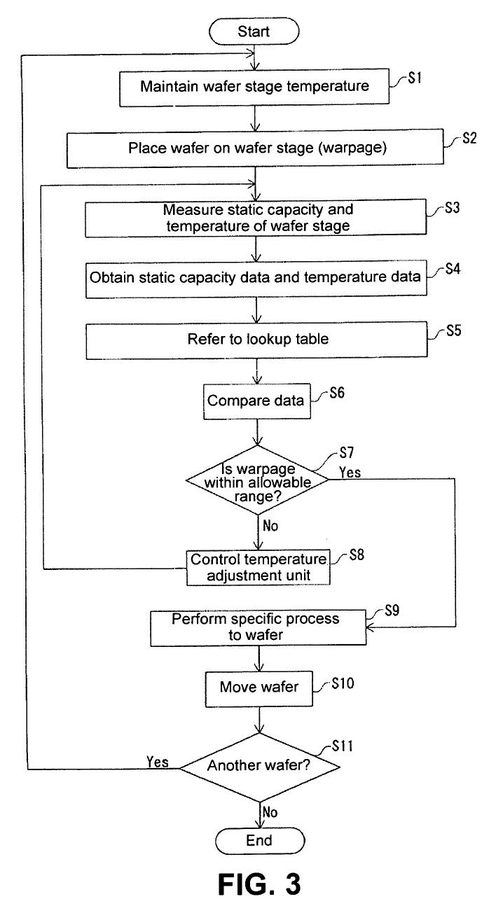

An operation of the substrate holding structure 10 will be explained next with reference to FIGS. 2 and 3. FIG. 3 is a flow chart showing the operation of the substrate holding structure 10 according to the embodiment of the present invention.

In the operation explained below, the wafer stage 20 is disposed in a process chamber for performing a specific process such as plasma CVD, dry etching, lamp annealing, and metal sputtering. In the operation explained below, a semiconductor wafer (referred to as the wafer) is placed on the wafer stage 20 for performing plasma CVD.

First, the first control unit 30 and the second control unit 40 start, so that the temperature measurement unit 24 and the temperature adjustment unit 26 in the wafer stage 20 become an operational state. Accordingly, in step S1, the wafer stage 20 is maintained at a specific set temperature. The specific set temperature is optimized according to a type of the object to be processed, i.e., the wafer, a manufacturing device, and a type of process. In the embodiment, the specific set temperature is preferably, for example, about 380° C.

In order to adjust the temperature, the control condition information, i.e., reference data, stored in the second storage unit 44 in advance is retrieved, and sent to the second control unit 40. Then, the control condition information is sent from the second control unit 40 to the temperature control unit 34. Accordingly, the temperature control unit 34 controls the temperature measurement unit 24 and the temperature adjustment unit 26 disposed in the wafer stage 20 to adjust the temperature according to the control condition information.

More specifically, the temperature measurement unit 24 measures the temperature of the wafer stage 20, and the temperature control unit 34 controls the temperature adjustment unit 26 according to the temperature thus measured to heat or cool the wafer stage 20, thereby adjusting the temperature thereof.

In step S2, the wafer is placed in the substrate placing area 20aa of the wafer stage 20. More specifically, the transportation unit 50 picks up one wafer from a loader side carrier for storing a plurality of wafers, and places the wafer in the substrate placing area 20aa.

At this time, heat of the wafer stage 20 is conducted to a contact surface of the wafer, thereby causing a temperature difference between a front surface and a backside surface of the wafer. As a result, the wafer is warped due to volume expansion associated with the temperature difference. That is, the wafer is deformed in a convex shape or a concave shape.

In step S3, from just before the wafer is placed to after the wafer is placed, the electrode control unit 32 of the first control unit 30 disposed outside the wafer stage 20 controls the static capacity measurement electrode 22 to measure the static capacity generated between the wafer stage 20 and the wafer, i.e., between the static capacity measurement electrode 22 and the wafer. Further, the temperature of the wafer stage 20 is also measured.

More specifically, a high frequency wave generator (not shown) disposed in the electrode control unit 32 applies a high frequency voltage having a frequency of, for example, 100 kHz to 10 MHz, and a voltage of 5 v to 10 V to the static capacity measurement electrode 22, thereby continuously measuring the static capacity.

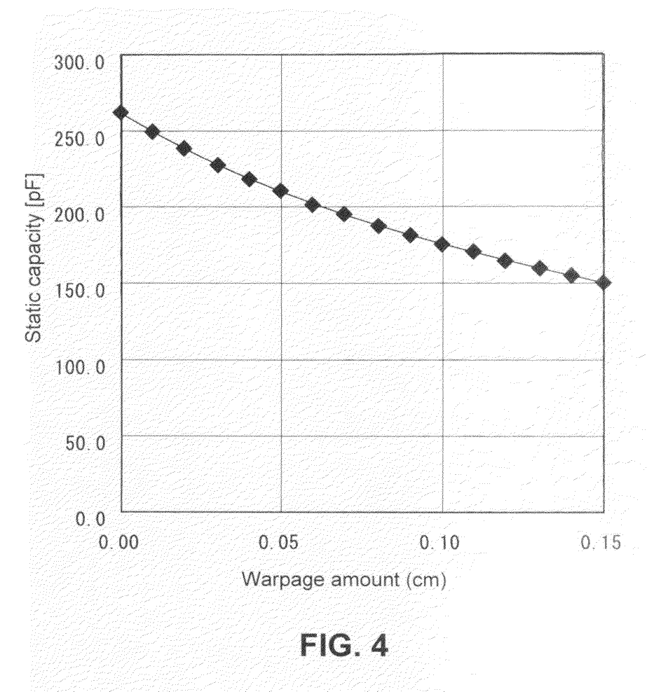

A simulation result of a relationship between the warpage amount of the wafer and the static capacity will be explained next with reference to Table and FIG. 4.

TABLE

| Δd (cm) | C (F) | C (pF) |
|---|---|---|
| 0.00 | 2.36E-10 | 263.0 |
| 0.01 | 2.50E-10 | 250.0 |
| 0.02 | 2.39E-10 | 239.1 |
| 0.03 | 2.29E-10 | 228.7 |
| 0.04 | 2.19E-10 | 219.1 |
| 0.05 | 2.10E-10 | 210.4 |
| 0.06 | 2.02E-10 | 202.3 |
| 0.07 | 1.95E-10 | 194.8 |
| 0.08 | 1.88E-10 | 187.8 |
| 0.09 | 1.81E-10 | 181.4 |
| 0.10 | 1.75E-10 | 175.3 |
| 0.11 | 1.70E-10 | 169.7 |
| 0.12 | 1.64E-10 | 164.4 |
| 0.13 | 1.59E-10 | 159.4 |
| 0.14 | 1.55E-10 | 154.7 |
| 0.15 | 1.50E-10 | 150.3 |

Table shows the simulation result of the relationship between the warpage amount of the wafer Δd (cm) and the static capacity C (F or pF).° Note that the relationship between the warpage amount of the wafer Δd and the static capacity C is stored in the second storage unit 44 in a readable form in advance as a lookup data table corresponding to a reference data group per type of usable wafer, a type of the wafer stage 20, and a combination of temperature and the likes.

FIG. 4 is a graph showing the relationship between the static capacity and the warpage amount and corresponding to Table according to the embodiment of the present invention. In FIG. 4, the vertical axis represents the static capacity (pF) and the horizontal axis represents the warpage amount (cm).

In the simulation, the wafer stage 20 is formed of alumina having a dielectric constant of 9.34 and a relative permeability of 8.85 E-14 (8.85×10⁻¹⁴). In the wafer stage 20, the center circular electrode 22a has a radius (r½) of 4.5 cm; a distance between the center circular electrode 22a and the circular ring electrode 22b is 1.5 cm; and a width r3′ within a width r3 of the circular ring electrode 22b overlapping with the wafer in a plan view along a radial direction thereof is 1.5 cm. Further, a distance between the center circular electrode 22a or the circular ring electrode 22b and the first main surface 20a, i.e., a contact surface of the wafer placed thereon, is 0.1 cm.

In the simulation, when the warpage amount of the wafer is detected, it is not necessary to consider factors varying the static capacity such as a diffused layer and an oxide layer thickness formed in an actual wafer. Accordingly, it is assumed that the wafer is formed of a metal plate.

In the simulation, a size of the static capacity measurement electrode 22 and a distance r2 between the center circular electrode 22a and the circular ring electrode 22b are determined such that an area of the center circular electrode 22a becomes equal to an area of the circular ring electrode 22b in the width r3′ thereof overlapping with the wafer in a plan view.

With the setting described above, it is possible to calculate the warpage amount of the wafer from capacities of the center circular electrode 22a, the circular ring electrode 22b, and the substrate according to one lookup table. When the area of the center circular electrode 22a is different from the area of the circular ring electrode 22b overlapping with the wafer, it is possible to create a different lookup table according to a difference in the areas. Alternatively, after a calculation is performed relative to a measurement value according to a area ratio, it is possible to calculate the warpage amount according to the lookup table.

As shown in Table and FIG. 4, when the wafer is not warped, or the warpage is removed, the static capacity becomes 263.0 pF. Accordingly, the temperature of the wafer stage 20 is controlled such that the static capacity becomes 263.0 pF. When the warpage amount increases, the static capacity gradually decreases. For example, as shown in Table, when the warpage amount if 0.15 cm, the static capacity becomes 150.3 pF.

As described above, the temperature control unit 34 controls the temperature measurement unit 24 to measure the temperature of the wafer stage 20. Then, the first calculation unit 36 converts the static capacity and the temperature thus measured to data readable and capable of calculation (referred to as static capacity data and temperature data) through, for example, a digital conversion with an A/D converter and an arbitrary appropriate data processing. The static capacity data and the temperature data are stored in the first storage unit 38 or transmitted to the second control unit 40.

In step S4, after the second control unit 40 retrieves the static capacity data and the temperature data stored in the first storage unit 38 or receives the static capacity data and the temperature data, the second calculation unit 42 of the second control unit 40 obtains the static capacity data and the temperature data as measurement values. It is preferred that the static capacity data and the temperature data are stored in the second storage unit 44 in a readable form if necessary.

In step S5, when the second calculation unit 42 of the second control unit 40 obtains the static capacity data and the temperature data as the measurement values, the second calculation unit 42 of the second control unit 40 refers to and retrieves the lookup table from the second storage unit 44.

In step S6, the second calculation unit 42 compares the static capacity data and the temperature data with the lookup table.

In the next step, the second calculation unit 42 calculates the warpage amount of the wafer Δd from the comparison result. When a difference between the static capacity data and zero data of the lookup table increases, that is, a value of the static capacity data increases, the warpage amount of the wafer increases. It is possible to obtain the warpage amount of the wafer Δd through finding a corresponding value to the static capacity thus measured upon comparing the measurement value with the corresponding value in the lookup table. The data processing described above may be an analog processing without the digital conversion.

In step S7, the second calculation unit 42 determines whether the warpage amount of the wafer Δd is zero, or is within an allowable range. The zero data, i.e., a reference for determining whether the warpage amount of the wafer Δd is zero, or is within the allowable range, is stored in the second storage unit 44 in a readable form. When the second calculation unit 42 determines that the warpage amount of the wafer Δd is not zero, or is not within the allowable range, the second calculation unit 42 of the second control unit 40 sends a control signal to the temperature control unit 34 through the first calculation unit 36.

In step S8, when the temperature control unit 34 receives the control signal, the temperature control unit 34 controls the temperature adjustment unit 26 to adjust the temperature of the wafer stage 20 such that the warpage amount of the wafer Δd becomes zero, or becomes within an allowable range. More specifically, the temperature adjustment unit 26 adjusts the temperature of the wafer stage 20 such that the static capacity moves toward the zero data while the static capacity is continuously measured in a real time. In the adjustment, a well-known device may be used for simply turning on and off the temperature adjustment unit 26, or for adjusting an extent of heating or cooling.

When the temperature adjustment unit 26 adjusts the temperature of the wafer stage 20 to increase, it is preferred that the temperature adjustment unit 26 quickly heats the wafer stage 20 in an extent greater than heating the wafer stage 20 to maintain the set temperature, i.e., dynamic heating. When the temperature adjustment unit 26 adjusts the temperature of the wafer stage 20 to decrease, it is preferred that quickly cools the wafer stage 20 in an extent greater than cooling the wafer stage 20 to maintain the set temperature. Accordingly, it is possible to shorten a period of time for removing the warpage.

In the embodiment, the temperature adjustment unit 26 adjusts the temperature of the wafer stage 20 while the static capacity is continuously measured in a real time. Accordingly, it is possible to accurately determine a timing when the warpage is removed, thereby minimizing a wait time until the warpage is removed.

When the static capacity measurement electrode 22 is formed of the center circular electrode 22a and a plurality of circular ring electrodes 22b arranged in an arrangement similar to the arrangement described above, it is possible to control the temperature adjustment unit 26 corresponding to static capacities separately measured with the center circular electrode 22a and the circular ring electrodes 22b.

For example, when the static capacity measured at a center of the wafer is greater than that measured at an outer circumference of the wafer, it is possible to control the temperature adjustment unit 26 such that the outer circumference of the wafer is heated or cooled in an extent greater than that for the center of the wafer. Accordingly, it is possible to reduce a difference in the temperatures on front and backside surfaces of the wafer, thereby removing the warpage thereof.

As described above, the temperature adjustment unit 26 adjusts the temperature of the wafer stage 20, so that the warpage of the wafer becomes zero, or becomes within the allowable range. That is, the temperature adjustment unit 26 heats or cools the wafer stage 20 until the warpage of the wafer becomes zero, or becomes within the allowable range.

Steps S3 to S8 are repeated all the time, i.e., in a real time, until the warpage of the wafer is removed. When Steps S3 to S8 are repeated intermittently with a specific interval, it is preferred to set the interval as small as possible.

As described above, in the embodiment, it is possible to accurately determine the timing when the warpage is removed, or within the allowable range, in a short period of time, thereby shortening a production time.

In step S9, after Steps S3 to S8 are performed or repeated, when the second calculation unit 42 determines that the amount of the warpage is zero (no warpage), or is removed, or in within the allowable range, a specific process, the CVD process in the embodiment, is performed relative to the wafer.

In step S10, after the specific process is performed, the transportation unit 50 moves the wafer from the substrate placing area 20aa, and stores the wafer in a carrier on an unload side.

In step S11, it is determined whether the specific process is performed relative to another wafer not processed yet. When it is determined that the specific process is performed relative to another wafer, the process returns to Step S1, so that Steps S1 to S11 described above are repeated for a specific number of times. When it is determined that the specific process is not necessary, the process is completed and moves to a next process.

Through the process described above, the operation of the substrate holding structure 10 is completed. In the embodiment, the wafer stage 20 is placed in the process room, i.e., the chamber for performing the film forming process such as chemical vapor deposition (CVD). Alternatively, the wafer stage 20 may be temporarily placed as a preliminary wafer stage outside the process room for removing a warpage of the object to be processed before the process.

The disclosure of Japanese Patent Application No. 2007-227305, filed on Sep. 3, 2007, is incorporated in the application by reference.

While the invention has been explained with reference to the specific embodiments of the invention, the explanation is illustrative and the invention is limited only by the appended claims.

What is claimed is:

1. A substrate holding structure, comprising:
a wafer stage including a first main surface and a second main surface opposite to the first main surface, said first main surface having a substrate placing area defined thereon;
a static capacity measurement electrode disposed in the wafer stage, said static capacity measurement electrode including a center circular electrode and at least one circular ring electrode disposed away from the center circular electrode and surrounding the center circular electrode for measuring a combined capacity among a substrate to be placed in the substrate placing area, the center circular electrode, and the circular ring electrode;
at least one temperature measurement unit disposed at a space between the center circular electrode and the circular ring electrode, or a space between the circular ring electrodes;
a temperature adjustment unit disposed in the wafer stage;
an electrode control unit connected to the center circular electrode and the circular ring electrode;
a temperature control unit connected to the temperature measurement unit and the temperature adjustment unit;
a storage unit;
a calculation unit connected to the storage unit; and
a control unit connected to the electrode control unit and the temperature control unit.

2. A substrate holding structure, comprising:
a wafer stage including a first main surface and a second main surface opposite to the first main surface, said first main surface having a substrate placing area defined thereon;
a static capacity measurement electrode disposed in the wafer stage and having a region just under the substrate placing area, said static capacity measurement electrode including a contour in a plan view overlapping with an outer area outside a contour of the substrate placing area, said static capacity measurement electrode further including a center circular electrode and at least one circular ring electrode disposed away from the center circular electrode and surrounding the center circular electrode for measuring a combined capacity among a substrate to be placed in the substrate placing area, the center circular electrode, and the circular ring electrode;
at least one temperature measurement unit disposed at a space between the center circular electrode and the circular ring electrode, or a space between the circular ring electrodes;
a temperature adjustment unit disposed in the wafer stage;
an electrode control unit connected to the center circular electrode and the circular ring electrode;
a temperature control unit connected to the temperature measurement unit and the temperature adjustment unit;
a storage unit;
a calculation unit connected to the storage unit; and
a control unit connected to the electrode control unit and the temperature control unit.

3. The substrate holding structure according to claim 1, wherein said circular ring electrode includes an outermost circular ring electrode having a contour in a plan view situated outside a contour of the substrate placing area.

4. The substrate holding structure according to claim 2, wherein said circular ring electrode includes an outermost circular ring electrode having a contour in a plan view situated outside the contour of the substrate placing area.

5. A method of producing a semiconductor device, comprising the steps of:
preparing the substrate holding structure according to claim 1;
placing the substrate in the substrate placing area of the wafer stage;
measuring a static capacity generated between the static capacity measurement electrode and the substrate with the static capacity electrode and the electrode control unit to obtain static capacity data at least when the substrate is placed in the substrate placing area;
comparing the static capacity data with lookup data stored in the storage unit and indicating a relationship between a warpage amount and a static capacity using the calculation unit;
determining a process of the temperature adjustment unit using the calculation unit so that a warpage of the wafer is removed or becomes within an allowable range using the calculation unit; and
controlling the temperature adjustment unit using the control unit to adjust a temperature of the wafer stage so that the warpage of the wafer is removed or becomes within the allowable range.

6. A method of producing a semiconductor device, comprising the steps of:
preparing the substrate holding structure according to claim 2;
placing the substrate in the substrate placing area of the wafer stage;
measuring a static capacity generated between the static capacity measurement electrode and the substrate with the static capacity electrode and the electrode control unit to obtain static capacity data at least when the substrate is placed in the substrate placing area;
comparing the static capacity data with lookup data stored in the storage unit and indicating a relationship between a warpage amount and a static capacity using the calculation unit;
determining a process of the temperature adjustment unit using the calculation unit so that a warpage of the wafer is removed or becomes within an allowable range using the calculation unit; and
controlling the temperature adjustment unit using the control unit to adjust a temperature of the wafer stage so that the warpage of the wafer is removed or becomes within the allowable range.
